(19) United States
(12) Patent Application Publication
(10) Pub. No.: US 2026/0322661 A1
(43) Pub. Date: Oct. 15, 2026

(54) DYNAMIC ADJUSTMENT OF CTLE COEFFICIENTS AND DUTY CYCLE FOR ACHIEVING HIGHER DATA RATES

(71) Applicant: XILINX, INC., San Jose, CA (US)

(72) Inventors: Amit VYAS, Hyderabad (IN); Santosh Krishna PARASURAMPURAM, Hyderabad (IN); Karthikeyan PALANISAMY, Coimbatore (IN)

(21) Appl. No.: 19/177,938

(22) Filed: Apr. 14, 2025

(51) Int. Cl. H04L 25/03; G11C 11/4076; H03K 5/156

(52) U.S. Cl. CPC H04L 25/03885; H03K 5/1565; G11C 11/4076

(57) ABSTRACT

The examples describe a system including a transmitter including a duty cycle adjuster and a receiver including an eye diagram analyzer configured to separately capture a two-dimensional (2D) eye diagram for a rising edge and a 2D eye diagram for a falling edge of a receiver path signal and a continuous-time linear equalizer (CTLE) adjuster configured to dynamically adjust CTLE coefficients. The receiver sends instructions to the transmitter to dynamically adjust a duty cycle to increase symmetry between the rising edge and the falling edge of the receiver path signal.

### TECHNICAL FIELD

Examples of the present disclosure generally relate to high-speed data communication systems, and, in particular, to dynamically adjusting continuous-time linear equalizer (CTLE) coefficients and duty cycle of receiver path signals to achieve higher data rates for memory.

### BACKGROUND

The continuous evolution of high-speed communication systems, such as double data rate 5 (DDR5), has been driven by the growing demand for increased data rates in modern applications. DDR5 memory, with its enhanced bandwidth and capacity, enables faster and more efficient data processing. To achieve higher data rates, DDR5 incorporates several technological advancements, including the use of higher clock frequencies, improved signaling techniques, and advanced power management schemes. These innovations allow DDR5 to deliver up to twice the performance of its predecessor, DDR4, while maintaining lower power consumption and higher reliability.

One of the challenges in achieving higher data rates in DDR5 lies in managing signal integrity and minimizing noise. As clock speeds increase, the timing margins for data transfer become increasingly tighter, necessitating the development of sophisticated equalization techniques, on-die termination, and decision feedback equalizers. Additionally, the introduction of dual-channel dual inline memory modules (DIMMs) and new features such as the memory controller's ability to handle multiple independent sub-channels further enhance parallelism and throughput. However, these design optimizations remain inadequate in further increasing the data transfer rates.

### SUMMARY

One example described herein is a system including a transmitter having a duty cycle adjuster and a receiver having an eye diagram analyzer configured to separately capture a two-dimensional (2D) eye diagram for a rising edge and a 2D eye diagram for a falling edge of a receiver path signal and a continuous-time linear equalizer (CTLE) adjuster configured to dynamically adjust CTLE coefficients. The receiver sends instructions to the transmitter to dynamically adjust a duty cycle to increase symmetry between the rising edge and the falling edge of the receiver path signal.

One example described herein is a system including a transmitter having a duty cycle adjuster and a receiver configured to send instructions to the transmitter to dynamically adjust a duty cycle parameter using the duty cycle adjuster based on two-dimensional (2D) eye diagrams for a rising edge and a falling edge of a signal. The duty cycle adjuster is configured to increase a symmetrical eye opening between the rising edge and the falling edge of the signal.

One example described herein is a method including separately capturing a two-dimensional (2D) eye diagram for a rising edge and a 2D eye diagram for a falling edge of a receiver path signal using an eye diagram analyzer located in a receiver, dynamically adjusting a duty cycle using a duty cycle adjuster located in a transmitter to increase symmetry between the rising edge and the falling edge of the receiver path signal, and dynamically adjusting CTLE coefficients using a continuous-time linear equalizer (CTLE) adjuster.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a system diagram including communication between a transmitter and a receiver including an eye diagram analyzer, according to an example.

FIG. 2 illustrates a continuous-time linear equalizer (CTLE) adjuster and a duty cycle adjuster of the receiver, according to an example.

FIG. 3A illustrates a first practical application for the real-time adjustment of CTLE coefficients and duty cycle of receiver path signals, according to an example.

FIG. 3B illustrates a second practical application for the real-time adjustment of CTLE coefficients and duty cycle of receiver path signals, according to an example.

FIG. 4A illustrates the impact of calibration on an eye shape of receiver data lines with static settings, according to an example.

FIG. 4B illustrates the impact of calibration on an eye shape of receiver data lines with dynamic settings, according to an example.

FIG. 5 illustrates a method for adjusting the CTLE coefficients and the duty cycle of receiver path signals, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the examples herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

High-speed data communication systems enable the rapid transmission of large amounts of information across various platforms. A key parameter for evaluating the performance of these systems is the concept of data eye margins, which refers to the time and voltage intervals where transmitted data signals can be reliably sampled without errors. However, as data rates increase, maintaining robust data eye margins becomes challenging. One of the primary issues impacting data eye margins is the use of static continuous-time linear equalization (CTLE). While CTLE is effective for compensating signal degradation caused by channel losses, a static CTLE configuration may fail to adapt to dynamic channel conditions, leading to suboptimal equalization and reduced signal integrity. Additionally, static duty cycles, which assume a fixed timing relationship between the transmitted data signal and the clock, can also limit higher data rates. These factors can result in a narrower eye opening, reducing the available margin for reliable data recovery.

Another challenge is the asymmetric eye opening between the rise and fall edges of the signals. This asymmetry occurs when the signal transitions are not symmetrical, which can introduce timing errors and cause further degradation of the data eye. This asymmetry often stems from static CTLE and duty cycles, which are unable to adapt dynamically to varying signal conditions and noise environments. This is an issue at higher data rates, where even slight mismatches between the rise and fall edges can lead to significant bit errors. As data rates continue to increase, addressing these issues becomes important for achieving the desired performance and reliability in high-speed data communication systems.

In view of such challenges, the examples present a method and system for employing dynamic adjustments of CTLE coefficients and duty cycle to improve data eye margins and enable higher data rates. Unlike traditional fixed systems, dynamic CTLE allows real-time adaptation to signal variations, compensating for channel losses and maintaining signal integrity across a wider range of operating conditions. Similarly, dynamic duty cycle adjustments ensure better symmetry between the rise and fall edges, effectively mitigating timing skew and enhancing overall performance.

By integrating these dynamic techniques, high-speed communication systems can achieve improved data eye margins, which enable reliable data transfer at speeds beyond 9 gigabits per second (Gbps). Such approach not only enhances system robustness but also reduces bit error rates, ensuring that performance gains are sustained under diverse operational scenarios. Additionally, the combination of dynamic CTLE and duty cycle adjustment provides a scalable approach, allowing future systems to adapt to even higher data rates without significant redesigns. The practical implementation of dynamic adjustments in CTLE and duty cycle involves the use of advanced feedback mechanisms and real-time monitoring systems. These mechanisms continuously evaluate signal quality and adjust equalization and timing parameters as needed. Such adaptive systems offer significant advantages over traditional approaches, particularly in environments with fluctuating noise levels and varying transmission distances.

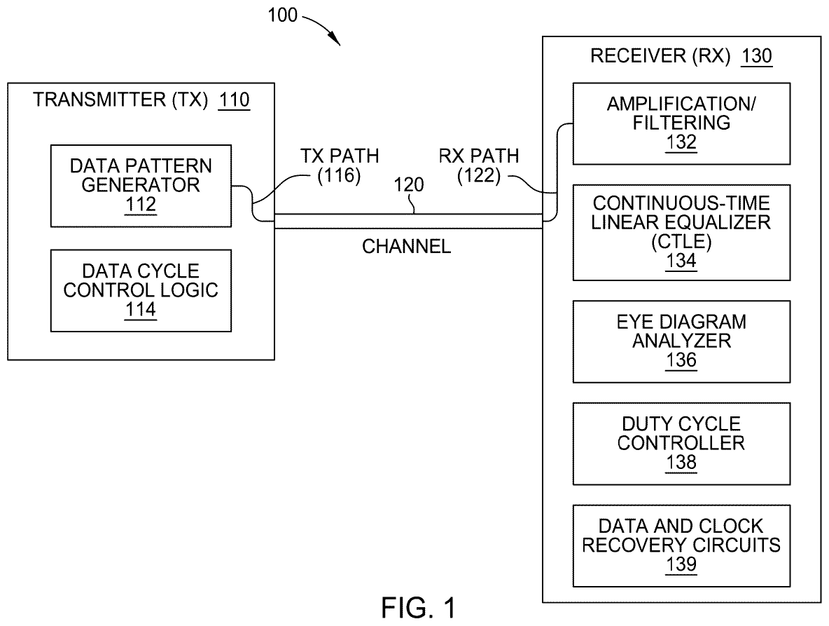

FIG. 1 illustrates a system diagram including communication between a transmitter and a receiver including an eye diagram analyzer, according to an example.

The system 100 includes a transmitter (TX) 110 and a receiver (RX) 130 communicating using a communication channel 120. The transmitter 110 includes a pattern generator 112 and duty cycle control logic 114. The receiver 130 includes amplification and filtering circuitry 132, a CTLE 134, an eye diagram analyzer 136, a duty cycle controller 138, and data and clock recovery (CDR) circuitry 139.

The pattern generator 112 generates custom-designed specialized data patterns (such as pseudorandom binary sequence (PRBS), alternating 1 s and 0 s, etc.) used for testing and real-time feedback. In other words, the pattern generator 112 is responsible for generating predefined or programmable data and command sequences used for testing, debugging or characterizing a dynamic random access memory (DRAM) interface. In particular, the pattern generator 112 can generate data (DQ) patterns and can also generate command (CMD) sequences.

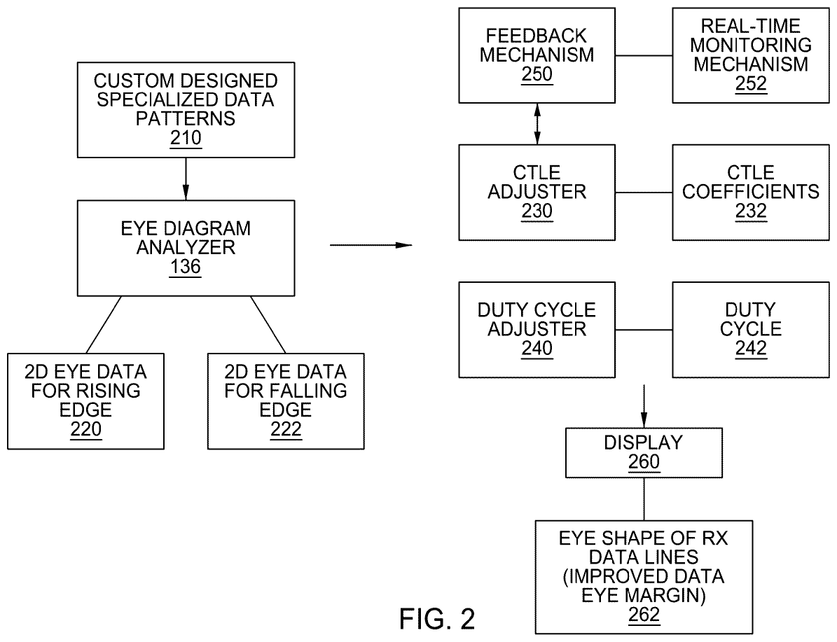

The custom-designed specialized data patterns 210 (FIG. 2) are specifically crafted data sequences or signal patterns used to test, diagnose, and optimize high-speed communication systems. The custom-designed specialized data patterns 210 are constructed to mimic real-world traffic and provide detailed insights into how a system performs under typical operational conditions. The custom-designed specialized data patterns 210 are used to stress-test various aspects of the system, such as signal integrity, timing margins, inter-symbol interference (ISI), and other potential issues that may arise in the transmission path.

PRBS patterns are commonly used to simulate random data traffic that mimics the unpredictable nature of real-world communications. PRBS patterns have a known statistical structure, allowing engineers to analyze the system's response under typical random data conditions. PRBS patterns are ideal for detecting issues such as jitter, noise, and ISI in the communication channel 120.

Alternating 1 s and 0 s are sequences of alternating high and low bits, such as 010101 or 101010. These patterns help test the system's response to high-frequency transitions. They are useful for assessing how well the communication channel 120 handles rapid transitions and identifying potential issues like attenuation or signal degradation at higher frequencies.

Long runs of identical bits are sequences of continuous 1 s or 0 s (e.g., 111111111 or 000000000) that help test the system's response to situations where no transitions occur for extended periods, which can exacerbate issues like ISI or pulse-width distortion (PWD). This pattern is valuable for testing the ability of the system to maintain signal integrity when no transitions are present, which can be problematic for some equalization techniques.

Data burst patterns involve bursts of high-density bits, such as a long sequence of 1 s followed by a sequence of 0 s, or vice versa. These bursts can stress the timing and frequency characteristics of the channel. Data burst patterns can simulate real-world traffic spikes, which may cause increased signal distortion or involve equalization adjustments.

Low and high-frequency transitions are patterns that target specific transition rates, including low-frequency (slow-changing) and high-frequency (rapid transitions) signals. Low-frequency transitions help evaluate the system's response to gradual changes in the signal, while high-frequency transitions test how the system handles rapid signal changes. These patterns are often used to evaluate channel bandwidth and equalizer performance.

Custom sequences for rise and fall edge optimization are custom patterns that can be specifically designed to emphasize the behavior of the rise edge and fall edge separately, allowing engineers to isolate and evaluate the performance of each edge in the eye diagram independently. This is useful in scenarios where timing asymmetry between the rise and fall edges may affect signal recovery. Specialized patterns can help diagnose these issues and guide optimization of both the source duty cycle and receiver equalization settings.

The duty cycle control logic 114 adjusts the transmitter's duty cycle based on feedback from the receiver 130. This ensures that the rise and fall edges of the signal are balanced and aligned with the optimal strobe signal timing. The duty cycle control logic 114 uses real-time control logic to modify the timing of the data signal to correct asymmetries. The strobe refers to a timing signal used to sample or latch data at specific points in time.

The TX path 116 takes the data output from the pattern generator 112 and drives it out onto the communication channel 120. This path may include drivers and voltage regulators to ensure signal integrity.

The communication channel 120 represents the communication medium between the transmitter 110 and the receiver 130, which can introduce distortions such as attenuation, ISI, jitter, and frequency-dependent effects.

The RX path 122 receives the signal from the communication channel 120 and passes it through an initial analog front-end for signal conditioning, such as amplification and filtering circuitry 132 to restore the integrity of the received signal.

The amplification and filtering circuitry 132 is used to ensure signal integrity and minimize noise. The amplification portion strengthens weak signals. The amplification portion increases signal amplitude to compensate for losses in long printed circuit board (PCB) traces or interconnects. The amplification portion ensures that signals meet minimum voltage levels needed by DRAM receivers. The filtering portion removes high-frequency noise and reduces reflections and ringing. The filtering portion eliminates unwanted electromagnetic interference (EMI) or power supply noise, and may use a low-pass filter (LPF) to smooth out unwanted spikes. The amplification portion also prevents signal integrity issues caused by impedance mismatches and may use termination networks to absorb reflections at high speeds. As such, the pattern generator 112 sends test patterns to the DRAM, the amplification circuitry ensures the signals are strong enough to be received correctly, and the filtering circuitry removes unwanted noise, preventing bit errors.

The CTLE 134 is responsible for equalizing the signal received from the communication channel 120 by compensating for attenuation and other distortions (e.g., ISI). In the examples, the CTLE coefficients are adjusted dynamically based on the feedback from the two-dimensional (2D) eye diagram analysis (rise and fall edge evaluation). A CTLE control block may be provided, which receives feedback on eye diagram performance (vertical and horizontal margins) and dynamically adjusts the CTLE filter coefficients (e.g., gain, filter bandwidth, equalization level). Stated differently, the CTLE 134 is an analog filter used in high-speed data receivers to compensate for signal losses and ISI caused by channel attenuation. The CTLE 134 boosts high-frequency components of the signal while attenuating low-frequency components. The CTLE 134 improves the eye opening in the eye diagrams by equalizing the signal before further processing. In one example, the CTLE 134 may be implemented as a high-pass filter with tunable gain to adjust the frequency response dynamically based on channel conditions. As such, the CTLE 134 enables high-frequencies to be restored to open the eye diagram for better detection.

The eye diagram analyzer 136 captures the 2D eye diagram for both rise and fall edges using high-speed oscilloscopes or signal analyzers. A feedback control system analyzes the eye diagram, providing real-time feedback on the quality of signal transitions. The feedback is used to adjust both the CTLE coefficients and duty cycle to optimize signal recovery. Stated differently, the eye diagram analyzer 136 is used to measure and visualize the quality of a high-speed digital signal. The eye diagram analyzer 136 evaluates signal integrity by showing how well the received signal maintains timing and voltage levels. The eye diagram analyzer 136 detects jitter, noise, ISI, and duty cycle distortion in serial data transmission and helps tune equalization and clock recovery settings.

An eye diagram plots multiple overlapping signal waveforms on a single graph (amplitude vs. time). A well-defined eye-opening means good signal quality. A closed or distorted eye indicates jitter, noise, or ISI issues. The key metrics for an eye diagram include eye height, eye width, and jitter. The eye height measures the signal-to-noise ratio (SNR). The eye width measures the timing margin and the jitter impact. The jitter measures the total, deterministic, and random jitter components.

The duty cycle controller 138 ensures that a clock signal maintains a precise 50% duty cycle. The duty cycle controller 138 minimizes clock asymmetry, reducing setup/hold violations, improves sampling accuracy in CDR circuits, and reduces bit errors (BER) caused by improper clock edge alignment. The duty cycle controller 138 monitors the high and low phases of a clock signal, adjusts the pulse width using, e.g., phase interpolators, delay cells, and charge pumps, and ensures that the clock transitions exactly at the midpoint of the data window. If the rise and fall edges are asymmetrical, the system may adjust the RX signal timing to align better with the optimal sampling point. This can include clock phase shifting or fine-tuning the duty cycle of the received signal.

Therefore, the CTLE 134 equalizes the signal by boosting high frequencies and compensating for ISI. The eye diagram analyzer 136 evaluates the quality of the equalized signal. If the eye is distorted, tuning is done via CTLE and duty cycle control. The duty cycle controller 138 ensures a balanced clock, preventing asymmetric sampling.

The CDR circuitry 139 extracts timing information from an incoming data stream. The CDR circuitry 139 ensures accurate data sampling without needing a separate clock signal. The CDR circuitry 139 extracts the clock signal, corrects jitter and phase misalignment, and maintains bit synchronization. Stated differently, the signal, after CTLE equalization and duty cycle adjustment, is sampled and passed to the CDR circuitry 139. The data recovery logic reconstructs the original transmitted data from the equalized signal, ensuring the data can be properly decoded and processed.

Therefore, improving data eye margins helps achieve higher data rates and ensures reliable data transmission in high-speed communication systems. One solution involves capturing and analyzing the 2D eye diagram separately for rise-edge and fall-edge sampled data. This approach provides detailed insights into the asymmetries and distortions in signal quality, enabling targeted adjustments to improve performance.

A data eye diagram is a visual representation of signal integrity and timing margins in a communication channel. A data eye diagram is generated by superimposing multiple bit transitions, creating a view of the signal's performance over time. A larger eye opening signifies better signal quality, while a narrower or distorted eye indicates challenges such as jitter, ISI, or duty cycle distortion. These issues are often exacerbated at high data rates due to reduced unit intervals and increased channel losses.

In high-speed systems, channel response dependency on data patterns can create asymmetric eye openings for rise-edge and fall-edge sampled data. Even with a nominally balanced 50% duty cycle in the strobe signal, variations in channel impedance, signal reflection, and interconnect properties can lead to discrepancies between the two transitions. These asymmetries reduce the effective eye margin and increase the likelihood of errors during data sampling.

To address these challenges, the examples begin by generating specialized data patterns that mimic real-world operating conditions. These patterns are transmitted through the communication channel, and the receiver captures the signal at the sampling points corresponding to rise edges and fall edges of the signal. The resulting 2D eye diagrams are analyzed separately for each transition type, providing insight into the different distortions affecting each.

The separation of rise-edge and fall-edge data allows the identification of specific issues, such as timing skew, unequal voltage swings, or channel-specific ISI. This analysis enables targeted optimizations, including real-time adjustments to the CTLE coefficients and duty cycle correction of the receiver's clock and CDR circuitry. By fine-tuning these parameters, the system compensates for channel-induced asymmetries and ensures symmetrical eye openings for both rise and fall transitions.

Another aspect of this approach is the ability to adjust the duty cycle at the transmitter's source. Any imbalance in the source-side duty cycle can exacerbate asymmetries in the receiver's data eye. By synchronizing the transmitter's duty cycle adjustments with the receiver's equalization settings, the system achieves an improvement in signal quality. This coordination reduces the timing uncertainty and optimizes the overall data eye margins.

The benefits of this method extend beyond improved eye margins. By ensuring a clear and symmetrical eye opening for both rise-edge and fall-edge data, the system can operate at higher data rates with reduced error rates. For example, improving data eye margins by addressing asymmetries can enable data rates exceeding 9 Gbps, representing a 25% increase in performance compared to systems without such optimizations. This performance gain is beneficial for applications in double data rate 5 (DDR5), low-power DDR5 (LPDDR5), and other high-speed memory and communication technologies.

Moreover, capturing and analyzing separate 2D eyes facilitates proactive diagnostics and system tuning. Engineers can identify channel-specific issues before they lead to significant performance degradation. This capability is valuable in dynamic environments where channel conditions may vary due to temperature, voltage, or workload changes. Real-time adjustment based on 2D eye analysis ensures consistent performance under diverse operating conditions.

As such, the technique of capturing and analyzing 2D eye diagrams separately for rise-edge and fall-edge sampled data helps improve data eye margins in high-speed systems. By using specialized data patterns, real-time adjustments, and coordinated optimizations, this approach addresses the causes of asymmetry and distortion in signal transmission. The resulting improvements in signal integrity and timing margins enable higher data rates, enhanced reliability, and greater system efficiency.

FIG. 2 illustrates a continuous-time linear equalizer (CTLE) adjuster and a duty cycle adjuster of the receiver, according to an example.

The eye diagram analyzer 136 receives the custom-designed specialized data patterns 210. The custom-designed specialized data patterns 210 help to simulate real-world traffic, stress-test the communication channel, isolate and diagnose issues, optimize equalization and timing, enhance eye diagram analysis, and validate design and performance.

The custom-designed specialized data patterns 210 replicate actual data traffic that would be transmitted in a typical communication system. By simulating realistic conditions, the custom-designed specialized data patterns 210 allow engineers to evaluate the performance of the system under expected operational loads. By introducing specific sequences and patterns, the system can be stressed in ways that reveal potential weaknesses, such as issues related to signal integrity, timing errors, or equalization performance. Different patterns highlight specific channel impairments, such as attenuation, ISI, crosstalk, or frequency-dependent distortions. Custom patterns allow engineers to diagnose where the channel is failing to meet expectations and to test specific adjustments (e.g., CTLE tuning or duty cycle correction). Custom patterns can provide the necessary data to optimize CTLE coefficients, timing adjustments, and other system parameters. This enables fine-tuning of the receiver 130 and the transmitter 110 for maximum performance. By using patterns that emphasize specific transitions or timing characteristics, these custom patterns make it easier to analyze the 2D eye diagrams for both rise-edge and fall-edge sampled data. This helps in evaluating eye openings, jitter, and signal margins with greater precision. Custom-designed patterns help verify that the system performs correctly and robustly across a wide range of conditions, ensuring that the design can handle the full spectrum of expected operational scenarios.

Custom-designed specialized patterns are powerful tools for testing, diagnosing, and optimizing high-speed communication systems. By mimicking real-world traffic and focusing on specific issues such as timing, transitions, and signal integrity, these patterns help fine-tune system parameters, optimize signal recovery, and improve overall system performance. Whether used for duty cycle adjustments, CTLE adjustments, or timing margin analysis, custom patterns play a critical role in ensuring the system meets the demands of modern high-speed data communication.

The eye diagram analyzer 136 analyzes eye data separately for the rising edge and for the falling edge of a signal being processed. The eye diagram analyzer 136 may include 2D eye data circuitry 220 for the rising edge and 2D eye data circuitry 222 for the falling edge.

An eye diagram is a graphical representation of a digital signal's quality as it travels from the transmitter 110 to the receiver 130. The eye diagram helps analyze signal integrity, jitter, noise, and overall system performance. An eye diagram is created by overlaying multiple bits of a digital signal on top of each other over time. The result looks like an eye. A wide, open eye indicates a clean, high-quality signal with minimal jitter and noise. A closed or distorted eye indicates signal degradation, cause by attenuation, ISI, jitter, or noise. As noted above, the key parameters of an eye diagram are eye height, eye width, jitter, and BER.

The transmitter 110, the receiver 130, and the CTLE 134 play a role in the quality of the eye diagram. The transmitter 110 generates and transmits the digital signal, determines signal strength, modulation format, and pre-emphasis, and poor transmitter design may cause eye closure due to signal degradation before transmission. The receiver 130 captures and decodes the transmitted signal, uses equalization techniques to restore the signal before data recovery, and a poor receiver design may result in ISI, jitter, and noise, leading to data errors. The CTLE 134 is a high-pass filter applied at the receiver side to compensate for channel losses and boosts high-frequency components wile attenuating low-frequency components to recover the signal clean. Before CTLE, the eye is partially closed due to attenuation and ISI, and after CTLE, the eye is wider and taller, improving bit detection.

Data eye margin issues associated with channel response are challenges that arise in high-speed communication systems when the signal quality deteriorates due to imperfections in the channel. The eye margin refers to the opening in the eye diagram, which is a visual representation of the signal's integrity at the receiver. A reduced or closed eye margin indicates poor signal quality, making it harder for the receiver 130 to correctly interpret the transmitted data. These issues are largely influenced by the channel's response, which includes the effects of attenuation, distortion, reflections, and noise. Factors contributing to data eye margin issues and their relationship with channel response include attenuation, ISI, reflection and impedance mismatch, channel crosstalk, jitter, power supply noise (PSN), and non-linearity in the channel response.

High-frequency components of the signal are attenuated more than low-frequency components due to, e.g., dielectric losses in the channel. This causes the edges of the signal to transition more slowly, reducing the vertical and horizontal eye margins. This leads to ISI. ISI is an overlapping of signal transitions caused by the spreading or smearing of previous signal pulses. This results in a smaller eye opening, as signals from different bits interfere, increasing bit errors. Further, signal reflections occur when there are impedance mismatches in the channel (e.g., at connectors, vias, or along PCB traces). This creates additional noise or distortion in the signal, reducing eye margins and possibly causing jitter. Channel crosstalk is an electromagnetic interference from adjacent channels or traces. It increases noise in the signal, which degrades the vertical eye margin and causes errors in the received data. Jitter is variability in the timing of signal transitions caused by channel impairments, clock instability, or noise. This reduces the horizontal eye margin, making it difficult for the receiver to sample the signal at the correct point in time. PDN noise is noise coupled into the channel from fluctuations in the power delivery network. This causes random or periodic disturbances in the signal, reducing both vertical and horizontal margins. Nonlinearity in the channel response relates to imperfections in the channel that cause nonlinear behavior, which distorts the signal in ways that cannot be compensated linearly. This leads to unpredictable degradation of the eye diagram, complicating equalization and correction efforts.

As such, the symptoms of data eye issues include, e.g., vertical eye closure, horizontal eye closure, skewed eye center, and noise-inducing closing. Vertical eye closure may refer to reduced vertical opening due to noise, attenuation, or reflections, making it hard to distinguish between logic levels (1 s and 0 s). Horizontal eye closure refers to reduced horizontal opening caused by jitter, ISI, or crosstalk, increasing sampling errors. Skewed eye center relates to asymmetric distortion due to unequal channel behavior or improper equalization. Noise-induced closing relates to random or deterministic noise components cause the eye to close.

In high-speed communication systems (e.g., DDR5, or serializer/deserializer (SerDes) links), ensuring adequate eye margins is beneficial for reducing BER, maintaining signal integrity, and meeting standards compliance. A smaller eye margin increases the likelihood of errors in interpreting data. Adequate eye margins indicate good signal quality and reliable communication. Many high-speed protocols specify minimum eye margin requirements for reliable operation. By analyzing the channel response and addressing its impairments, the eye margin can be improved, ensuring robust and error-free data transmission.

The asymmetric eye opening for rise-edge versus fall-edge sampled data, even with a 50% duty-cycle strobe, arises due to the dependency of the channel response on the data patterns and nonlinearities in the signal transmission process. This asymmetry is a common issue in high-speed communication systems and is caused by several factors related to the interaction between the transmitted data and the channel characteristics. The causes of an asymmetric eye opening for rise-edge versus fall-edge sampled data include ISI, channel non-linearities, attenuation, pulse-width distortion, strobe and sampling mismatching, crosstalk and noise coupling.

ISI occurs when the channel's response to previous bits influences the current bit, creating residual energy that interferes with subsequent signal transitions. The rise and fall transitions are affected differently because their shape and amplitude depend on the preceding data pattern (e.g., long sequences of 1 s followed by a 0 versus alternating 1 s and 0 s). This may result in asymmetric eye openings for rising and falling edges due to unequal ISI contributions.

Real-world channels exhibit nonlinear behavior, such as uneven amplification or distortion of high-frequency components, especially in long traces, connectors, or cables. Nonlinearities can distort rising and falling edges differently, particularly if the rise and fall times are slightly mismatched due to circuit imperfections. As a result, uneven edge timing and amplitudes may cause the asymmetry in the eye diagram.

High-frequency components of the signal are attenuated more than low-frequency components due to, e.g., dielectric losses. Rising edges (often including more high-frequency content) may degrade differently than falling edges, depending on the preceding data pattern. As a result, unequal transitions may lead to asymmetric eye openings.

PWD occurs when the rise and fall times of the signal differ due to imperfections in the transmitter or channel. Even with a nominal 50% duty cycle, the actual pulse width of logic 1 and 0 levels may not be equal, skewing the sampling points. As a result, uneven rise and fall transitions may trigger asymmetry in the eye diagram.

While the strobe nominally operates at a 50% duty cycle, small mismatches in the timing of the strobe relative to the data transitions can affect rise and fall sampling differently. This can exaggerate asymmetry already introduced by the channel or transmitter. This may result in a biased or uneven eye opening.

Crosstalk from adjacent channels or noise coupling from the power delivery network can inject disturbances that vary depending on the data pattern. Rising and falling edges are affected differently, depending on the interference timing relative to the transitions. This may result in unequal noise contributions, further exacerbating asymmetry in the eye.

The impact on the eye diagram can be vertical eye asymmetry, horizontal eye asymmetry, and skewed sampling points. For vertical eye asymmetry, the voltage levels for rising and falling edges differ due to data-dependent ISI or channel nonlinearities. For horizontal eye asymmetry, the timing of rising and falling edges deviates due to jitter, ISI, or pulse-width distortion. For skewed sampling points, asymmetric distortions may shift the optimal sampling point, reducing timing margins.

One approach to resolve such issues is to handle and process the 2D eye data separately for the rising edge and separately for the falling edge. Separating 2D eye data circuitry for rising and falling edges improves timing analysis, jitter compensation, and signal integrity. This is beneficial in, e.g., non-return-to-zero (NRZ) and pulse amplitude modulation 4-level (PAM4) signaling.

A 2D eye diagram represents both time (horizontal axis) and voltage levels (vertical axis) over multiple signal transitions. The rising edge is the transition from low to high (0→1). The falling edge is the transition from high to low (1→0). The timing behavior of rising and falling edges can be asymmetrical due to channel distortion, ISI, and jitter. Analyzing them separately allows more precise tuning of receiver equalization and CDR. Duty cycle distortion and asymmetric slew rates cause different delays for rising versus falling edges. As such, the examples present 2D eye data circuitry 220 for the rising edge and 2D eye data circuitry 222 for the falling edge.

Random jitter (RJ) and deterministic jitter (DJ) affect the rising and falling edges differently. Separating the analysis allows the CDR circuitry 139 to apply different correction factors to each transition. In real systems, clock signals may not have a perfect 50% duty cycle, leading to asymmetric transitions. Separate circuitry ensures correct sampling points for both edges, reducing bit errors. Due to PCB trace imperfections, rising edges may transition faster or slower than falling edges. ISI can distort these edges differently. Independent tracking allows for better equalization per edge. In PAM4, there are three transition levels instead of just one (unlike NRZ). Each transition (e.g., level 0→1 vs. level 2→3) experiences different distortions. Separate edge tracking ensures each transition is equalized optimally.

The above approach of using the 2D eye data circuitry 220 for the rising edge and the 2D eye data circuitry 222 for the falling edge can be enhanced by also including a CTLE adjuster 230 and a duty cycle adjuster 240. The CTLE adjuster 230 allows for real-time adjustment of CTLE coefficients 232 and the duty cycle adjuster 240 allows for real-time adjustment of the duty cycle 242. For the CTLE adjuster 230, the rising edge and the falling edge refer to a high-frequency signal passing through the equalizer. The CTLE adjuster 230 shapes the signal by boosting high-frequency components to compensate for channel losses. For the duty cycle adjuster 240, the rising and falling edge refer to the clock signal or data signal whose duty cycle is being corrected. The duty cycle adjuster 240 shifts either the rising edge or the falling edge to achieve 50% duty cycle. The duty cycle adjuster 240 is located in the transmitter 110. The transmitter 110 is responsible for adjusting the duty cycle.

In operation, the receiver 130 includes the eye diagram analyzer 136 and is logging data related to the 2D eye data for both the rising edge and the falling edge. This data can be referred to as N-sample data and P-sample data. The data relates to, e.g., eye width and eye height. The N-sample data is different than the P-sample data, and the difference is used to measure the eye shape. Once this data is generated, instructions are sent to the transmitter 110 to correct for the duty cycle. The duty cycle adjuster 240 of the transmitter 110 thus corrects or adjusts the duty cycle according to the data received from the receiver 130. The updated or revised duty cycle data is then transmitted to the receiver 130, which uses such data to re-measure the eye shape. This process may repeat multiple times until an acceptable duty cycle has been achieved for improving the eye shape. After this improvement is made, then the CTLE adjuster 230 located in the receiver 130 may be activated to further improve the eye shape. However, it is noted that the decision to increase the duty cycle parameter or decrease the duty cycle parameter is made by the receiver 130, not the transmitter 110. The receiver 130 determines the necessary correction and communicates adjustments back to the transmitter 110. Stated differently, the transmitter 110 does not automatically or autonomously adjust the duty cycle. Instead, the transmitter 110 modifies its duty cycle using the duty cycle adjuster 240 based on instructions received from the receiver 130.

The real-time adjustment of CTLE coefficients 232 and the duty cycle 242 of the receiver path signals (data strobe and associated data lines) based on the receiver channel's response is a solution to address asymmetric eye openings caused by channel impairments and data-pattern dependencies. This approach helps to dynamically compensate for signal distortion, improve signal integrity, and ensure optimal data recovery.

CTLE 134 compensates for signal degradation due to channel effects such as attenuation, ISI, and frequency-dependent loss. By adjusting the CTLE coefficients 232 in real-time, using the CTLE adjuster 230, and the receiver 130 can dynamically optimize the equalization based on current channel conditions. Channels often have time-varying characteristics due to temperature changes, noise, or changes in signal frequency content. Real-time adjustments help to respond to these fluctuations. Data patterns, especially long sequences of identical bits, can exacerbate ISI. By adjusting CTLE coefficients on-the-fly, or dynamically, in real-time, the system can equalize the channel for varying data patterns, improving the symmetry of both rise and fall edges. Real-time adjustments allow for maintaining a consistent vertical and horizontal eye margin, even when channel impairments change. This leads to reduced bit errors and improved signal quality.

This may be implemented using either a feedback loop or through auto-tuning. The feedback loop may use a feedback mechanism (or feedback circuitry) that continuously monitors the quality of the received signal (e.g., by analyzing the eye diagram or BER) and adjusts the CTLE coefficients 232 accordingly. The auto-tuning approach may implement algorithms that can autonomously adapt the gain, frequency response, and filter characteristics of the CTLE 134 based on the current data pattern and channel response.

The CTLE coefficients 232 are numerical values or settings that adjust the frequency response of the equalizer. These coefficients define how much gain or attenuation is applied at different frequency ranges. Common types of CTLE coefficients 232 include boost coefficients, DC gain coefficients, peaking coefficients, pole-zero placement coefficients, and adaptation coefficients. Boost coefficients determine the amount of amplification applied to high-frequency components. Higher boost compensates for more severe high-frequency losses but may increase noise sensitivity. DC gain coefficients control the baseline amplification for low-frequency components (DC gain) and help maintain signal integrity without over-amplifying the low-frequency content. A peaking coefficient adjusts the shape of the frequency response curve, specifically how sharply the gain transitions from low to high frequencies. It defines the resonance or peaking effect of the equalizer. A pole-zero placement coefficient includes poles and zeros in the frequency response to determine the specific frequencies where gain changes occur. These placements are controlled by coefficients that affect the equalizer's bandwidth and cutoff frequencies. An adaption coefficient allows the equalizer to dynamically adjust to changing channel conditions or signal properties.

The duty cycle of the data strobe and associated data lines affects the timing of signal sampling. If the duty cycle is mismatched or unstable, it can lead to misaligned sampling between the rising and falling edges of the data, exacerbating asymmetry in the eye diagram. By adjusting the duty cycle of the strobe and data lines in real-time, the system can ensure that the strobe is aligned optimally with the center of the data eye. This reduces the timing skew between rising and falling edges, leading to a more balanced eye opening. By correcting duty cycle distortions caused by channel effects, the receiver 130 can more reliably capture the data, even under varying conditions. Adaptive duty cycle adjustment can also help to mitigate jitter by aligning the sampling points more effectively, making the system less sensitive to phase noise or timing instability.

This may be implemented using dynamic timing adjustments, duty cycle monitoring, or feedback-based duty cycle control. The dynamic timing adjustment uses a timing controller that adjusts the strobe and data signal timing in real-time based on the received signal quality. This may involve phase-locking the strobe to the received data signal. The duty cycle monitoring continuously monitors the duty cycle of the RX signals and use real-time metrics (e.g., eye diagram, jitter measurements, or BER) to fine-tune the duty cycle alignment. The feedback-based duty cycle control can be implemented using a feedback mechanism where the receiver adjusts the timing of the strobe based on the response of the receiver channel.

The benefits of using the CTLE adjuster 230 to dynamically adjust the CTLE coefficients 232 and the duty cycle adjuster 240 to dynamically adjust the duty cycle 242 include improved signal integrity, dynamic adaptation to channel variability, enhanced timing margins, increased data throughput and reliability, and reduced complexity.

The real-time adjustment of CTLE coefficients 232 and the duty cycle 242 minimizes the degradation of signal quality due to channel effects like ISI and attenuation, leading to clearer signal transitions and reduced errors. The approach adapts to the dynamic nature of high-speed communication channels, which may experience changing conditions over time (e.g., temperature variations, cable flexing, or noise fluctuations). By ensuring that both the data signal and strobe are properly aligned, the system can maintain better timing margins, reducing the chance of errors caused by improper sampling or misalignment. With a consistent and symmetric eye opening, the receiver 130 can operate at higher data rates with lower BER, ensuring reliable communication even under challenging channel conditions. Instead of relying on static pre-configured settings, the system 100 can continuously adjust to the actual channel conditions, reducing the need for complex manual calibration and allowing for more flexible design.

Real-time adjustment of CTLE coefficients and duty cycle of the RX path signals based on the receiver channel's response is an effective and adaptive solution to combat asymmetric eye opening. By dynamically compensating for channel-induced distortions and improving signal sampling alignment, this approach helps ensure reliable high-speed data transmission with optimized eye margins and reduced bit errors.

The real-time, dynamic adjustments of the CTLE coefficients 232 and the duty cycle 242 may be implemented using a feedback mechanism 250 (or feedback circuitry) and a real-time monitoring mechanism 252 (or monitoring circuitry). Thus, the practical implementation of dynamic adjustments in CTLE and duty cycle involves the use of advanced feedback mechanisms or circuitry and real-time monitoring systems. These mechanisms continuously evaluate signal quality and adjust equalization and timing parameters as needed. Such adaptive systems offer significant advantages over traditional approaches, particularly in environments with fluctuating noise levels and varying transmission distances.

The eye diagrams may be displayed on a display 260 showing the eye shape 262 of the RX lines with an improved data eye margin.

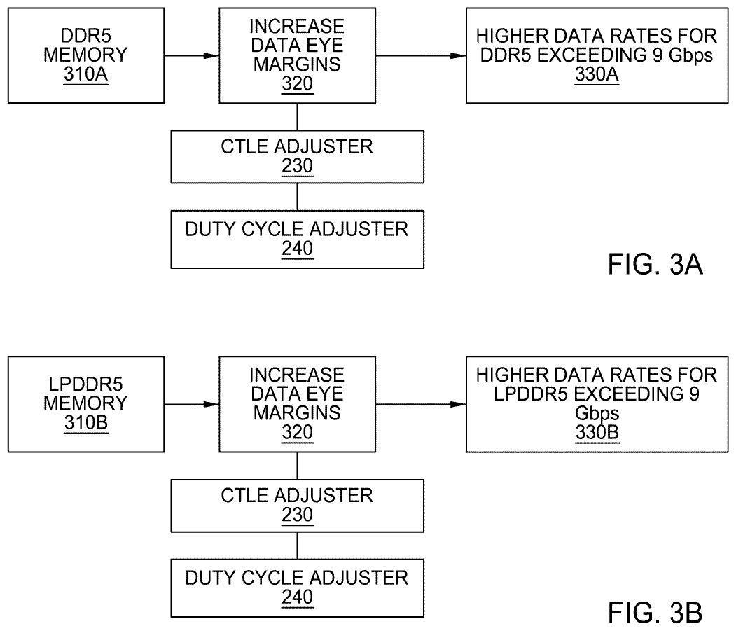

FIG. 3A illustrates a first practical application for the real-time adjustment of CTLE coefficients and duty cycle of receiver path signals, according to an example.

Double data rate 5 (DDR5) is the fifth generation of DDR synchronous dynamic (SDRAM), a type of volatile memory commonly used in personal computers (PCs), laptops, and servers. DDR5 is designed to provide higher data transfer rates and improved energy efficiency compared to its predecessor, DDR4. DDR5 offers higher data transfer speeds, with rates starting at 4800 mega-transfers per second (MT/s) and going beyond 8000 MT/s in overclocked modules. DDR5 operates at a lower voltage (1.1V compared to 1.2V for DDR4), reducing overall power consumption.

In one example, DDR5 memory 310A may be used for increasing the data eye margins 320. The data eye margins may be increased by using the CTLE adjuster 230, the duty cycle adjuster 240, as well as the 2D eye data circuitry 220 for the rising edge and 2D eye data circuitry 222 for the falling edge. This will result in higher data rates 330A for the DDR5 memory 310A, which can exceed 9 Gbps.

In one example, DDR5 supports data rates ranging from 4.8 Gbps to 8.4 Gbps, with future modules potentially going beyond 10 Gbps. By increasing the data eye margins, DDR5 can push its performance limits to higher data rates (e.g., exceeding 10.5 Gbps). This improves bandwidth per module, enhancing performance for memory-intensive applications such as artificial intelligence/machine learning (AI/ML) workloads.

FIG. 3B illustrates a second practical application for the real-time adjustment of CTLE coefficients and duty cycle of receiver path signals, according to an example.

Low-power DDR5 (LPDDR5) is a specialized version of DDR5 designed for mobile devices like smartphones, tablets, and ultra-thin laptops. LPDDR5 prioritizes low power consumption to extend battery life while maintaining high performance. LPDDR5 has lower power consumption than DDR5, with operating voltages as low as 0.6V to 1.05V. LPDDR5 offers speeds up to 8500 MT/s, suitable for high-performance tasks in mobile devices.

In one example, LPDDR5 memory 310B may be used for increasing the data eye margins 320. The data eye margins may be increased by using the CTLE adjuster 230, the duty cycle adjuster 240, as well as the 2D eye data circuitry 220 for the rising edge and 2D eye data circuitry 222 for the falling edge. This will result in higher data rates 330B for the LPDDR5 memory 310B, which can exceed 9 Gbps.

In one example, LPDDR 5 supports data rates up to 8.533 Gbps, designed for low-power, high-performance applications like smartphones, Internet-of-Things (IoT) devices, and automotive systems. By increasing the data eye margins, LPDDR5 can achieve data rates exceeding even 10 Gbps, significantly improving power efficiency per bit and supporting higher-resolution video processing, AI tasks, and faster app loading times in mobile devices.

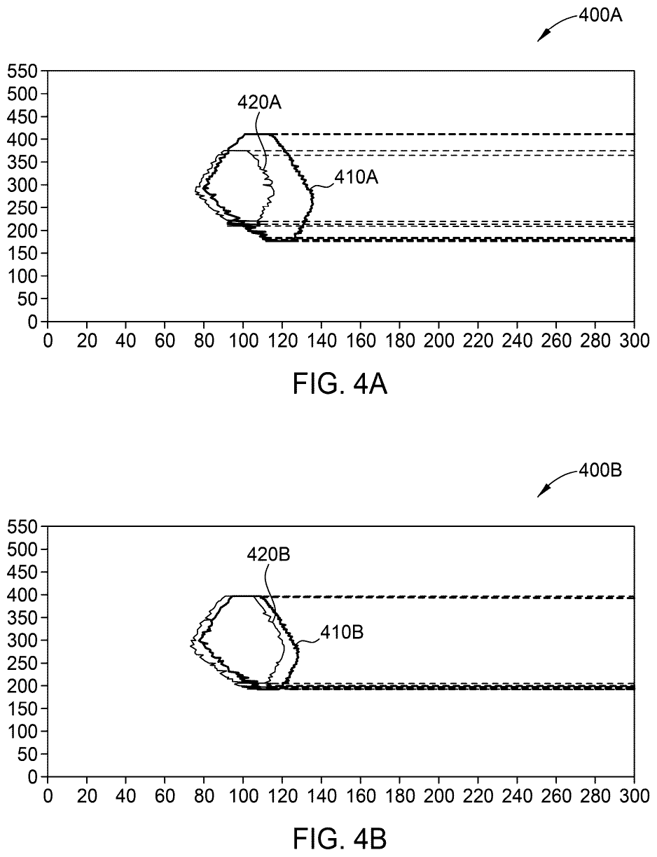

FIG. 4A illustrates the impact of calibration on an eye shape of receiver data lines with static settings, according to an example.

The graph 400A shows the eye shape 410A with respect to the rising edge and the eye shape 420A with respect to the falling edge. The graph 400A shows asymmetry between the eye shape 410A and the eye shape 420A. For example, the eye shape 420A is much larger than the eye shape 410A. This results in a horizontal shift or offset of one eye shape with respect to the other.

The system includes two samplers. For example, an even sampler and an odd sampler. The even sampler may be used for the positive edges and the odd sampler may be used for the negative edges. By sampling at both positive and negative edges, the effective doubling rate is doubled, leading to better eye diagram reconstruction. Using two samplers helps capture more data points per unit interval. As such, the CDR circuitry 139 can use both the rising and falling edge samples to adjust timing offsets dynamically. This helps in compensating for asymmetric distortions in the channel, and asymmetry in the eye diagram of the graph 400A.

Also, there are two clock components, a P-clock and an N-clock. The P-clock or positive clock aligns with the rising edge of the signal and the N-clock or negative clock aligns with the falling edge of the signal. As such, since both edges of the signal are sampled, the data rate is doubled without increasing the fundamental clock frequency. Moreover, having separate clock domains for the rise and fall edges reduces clock-to-data timing mismatches. Also, if the duty cycle is skewed (e.g., the rise edge is faster than the fall edge), separate N-clock and P-clock allows for independent tuning, which helps correct duty cycle distortion. The N-clock and the P-clock can be adjusted independently.

FIG. 4B illustrates the impact of calibration on an eye shape of receiver data lines with dynamic settings, according to an example.

The graph 400B shows the eye shape 410B with respect to the rising edge and the eye shape 420B with respect to the falling edge. The graph 400B shows symmetry between the eye shape 410A and the eye shape 420A. For example, the eye shape 420A is the same as the eye shape 410A. The eye opening are the same. In other words, the eye shape 410B is the same size as the eye shape 420B. Thus, using the eye diagram analyzer 136, the CTLE adjuster 230, and the duty cycle adjuster 240, the eye shapes or eye openings are matched to be the same size, thus reducing asymmetry between the rising and falling edges of the eye openings.

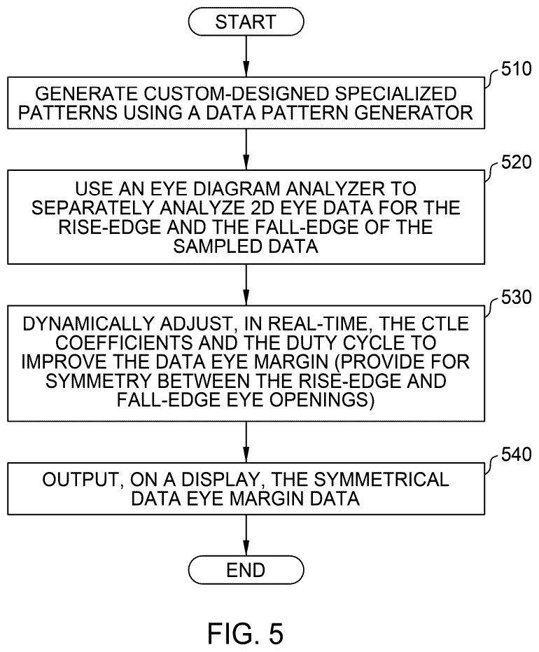

FIG. 5 illustrates a method for adjusting the CTLE coefficients and the duty cycle of receiver path signals, according to an example.

At 510, custom-designed specialized patterns are generated using a data pattern generator. The patterns are designed based on realistic use cases that mimic the types of data expected to be transmitted under normal operating conditions. These patterns include transitions that stress the signal integrity and timing of the edges.

At 520, an eye diagram analyzer is used to separately analyze 2D eye margin data for the rise-edge and the fall-edge of the signal. An oscilloscope or digital communication analyzer can be used to capture the signal at both the rising edge and the falling edge of the data signal. For each edge, a 2D eye diagram is generated based on the sampled data and record the eye diagram for both edges. The 2D diagrams can be evaluated to assess symmetry, jitter, noise, and margin.

At 530, CTLE coefficients and the duty cycle are dynamically adjusted, in real-time, to improve the data eye margin by providing for symmetry between the rise-edge and fall-edge eye openings. Based on the results, the system parameters are adjusted. The system parameters may include CTLE settings, duty cycle corrections, and phase adjustments. For the CTLE settings, more equalization may be applied to the edge that shows greater signal degradation. For the duty cycle correction, the strobe signal timing may be fine-tuned to ensure both edges are sampled at optimal points. For the phase adjustments, if the channel introduces skew, the phase of the receiver's sampling clock may be adjusted to better align with the edges.

At 540, symmetrical eye margin data is output to a display.

The benefits of the example approach include that, by analyzing the rise-edge and fall-edge separately, it can be determined if there is any asymmetry caused by the channel. This is useful for identifying issues related to PWD, frequency-dependent loss, or ISI that may disproportionately affect one edge. This approach also isolates the impact of crosstalk or differential skew between the signal paths, which may manifest differently for rise and fall edges. By using specialized patterns, conditions are created that more closely match real-world traffic. This provides a more realistic test environment to identify problems that may not be visible with simpler test patterns. This example method provides a more thorough examination of the signal integrity, capturing subtle imperfections that may otherwise go unnoticed. With separate eye diagram analysis, it becomes easier to determine the optimal sampling points for both rise and fall edges independently. This allows for fine-tuning the strobe timing, CTLE coefficients, and duty cycle adjustment mechanisms specifically for each edge, leading to better timing margins and more reliable data transmission. If the system supports dynamic equalization (e.g., real-time adjustment of CTLE coefficients), capturing separate eye diagrams can guide real-time compensations. For example, if the rise edge shows significant distortion compared to the fall edge, the system can apply more compensation to the rising edges.

The benefits of dynamically adjusting CTLE and duty cycle extend beyond immediate improvements in data eye margins. This approach enables communication systems to operate at significantly higher data rates with greater reliability, reducing the risk of data corruption and ensuring consistent performance. Dynamic adjustments also optimize power efficiency by adapting equalization levels to the specific requirements of the channel, avoiding unnecessary power consumption. Additionally, the ability to fine-tune duty cycles in real time enhances compatibility across a wide range of devices and operating conditions, promoting interoperability in complex communication environments. By ensuring a clear and symmetrical eye opening for both rise-edge and fall-edge data, the system can operate at higher data rates with reduced error rates. For example, improving data eye margins by addressing asymmetries can enable data rates exceeding 9 Gbps, representing a 25% increase in performance compared to systems without such optimizations. This performance gain is critical for applications in DDR5, LPDDR5, and other high-speed memory and communication technologies.

Another advantage is the reduction in design complexity and cost. By leveraging dynamic adjustments, system architects can minimize the need for overengineering hardware components to account for worst-case scenarios. This flexibility not only simplifies the design process but also accelerates time-to-market for high-speed communication products. Dynamic CTLE and duty cycle adjustments also contribute to improved thermal performance. By dynamically adapting to changing conditions, these systems can operate within optimal temperature ranges, reducing the risk of overheating and extending the lifespan of critical components.

Thus, the combination of dynamic CTLE tuning and duty cycle adjustment, coupled with edge-specific data analysis, offers several significant benefits. First, it enables higher data rates by maximizing the effective bandwidth of the communication channel. Second, the ability to adapt dynamically to real-time conditions reduces the likelihood of data loss or errors, improving overall system robustness. Third, the separate analysis of rise-edge and fall-edge sampled data provides a more comprehensive understanding of signal behavior, allowing for targeted optimizations that enhance signal quality and timing precision.

In conclusion, addressing data eye margin challenges is valuable for achieving higher data rates in modern communication systems. The dynamic adjustment of CTLE and duty cycle parameters helps in optimizing signal integrity and mitigating the effects of channel impairments. By continuously adapting to changing signal conditions, this approach ensures that the system maintains robust performance, even in the presence of jitter, noise, and other distortions that may degrade data eye margins. The examples rely on the separate capture and analysis of 2D eye data for rise-edge and fall-edge sampled signals. This approach provides insights into asymmetries and timing disparities that conventional methods may overlook. By isolating and addressing issues specific to each edge, the examples can implement more precise corrective measures, resulting in a more symmetrical and well-defined data eye. This, in turn, enhances the overall reliability and efficiency of high-speed data transmission.

The combination of dynamic CTLE tuning and duty cycle adjustment, coupled with edge-specific data analysis is a strategy for overcoming the limitations of traditional equalization techniques. This approach not only improves the achievable data rates but also extends the operational range of communication links, making it valuable for applications involving high bandwidth and low latency. Further, the insights gained from 2D eye analysis can inform the development of advanced algorithms and hardware architectures tailored for next-generation systems.

By integrating these dynamic techniques, high-speed communication systems can achieve improved data eye margins for reliable data transfer at speeds beyond 9 Gbps. This approach not only enhances system robustness but also reduces bit error rates, ensuring that performance gains are sustained under diverse operational scenarios. Additionally, the combination of dynamic CTLE and duty cycle adjustment provides a scalable approach, allowing future systems to adapt to even higher data rates without significant redesigns.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A system comprising:
a receiver including:
an eye diagram analyzer configured to separately capture a two-dimensional (2D) eye diagram for a rising edge and a 2D eye diagram for a falling edge of a receiver path signal; and
a continuous-time linear equalizer (CTLE) adjuster configured to dynamically adjust CTLE coefficients,
wherein the receiver sends instructions to a transmitter to dynamically adjust a duty cycle to increase symmetry between the rising edge and the falling edge of the receiver path signal.

2. The system of claim 1, wherein optimal CTLE coefficient and duty cycle settings are determined based on the captured 2D eye diagrams for the rising edge and the falling edge.

3. The system of claim 1, wherein increasing the symmetry results in a more symmetrical eye opening between the rising edge and the falling edge of the receiver path signal.

4. The system of claim 1, wherein increasing the symmetry results in improved data eye margins configured to enable data transfer at speeds of at least 9 gigabits per second (Gbps).

5. The system of claim 1, wherein the dynamic adjustments of the CTLE coefficients and the duty cycle maintain a consistent vertical and horizontal eye margin.

6. The system of claim 1, wherein feedback circuitry and real-time monitoring circuitry is used for the dynamic adjustments of the CTLE coefficients and the duty cycle.

7. The system of claim 1, wherein the eye diagram analyzer receives custom-designed specialized data patterns configured to replicate data traffic that emphasizes specific transitions or timing characteristics to analyze the 2D eye diagrams for the rising edge and the falling edge of the receiver path signal.

8. A system comprising:
a transmitter including a duty cycle adjuster; and
a receiver configured to send instructions to the transmitter to dynamically adjust a duty cycle parameter using the duty cycle adjuster based on two-dimensional (2D) eye diagrams for a rising edge and a falling edge of a signal,
wherein the duty cycle adjuster is configured to increase symmetry of an eye opening between the rising edge and the falling edge of the signal.

9. The system of claim 8, wherein the receiver includes an eye diagram analyzer configured to separately capture the 2D eye diagrams for the rising edge and the falling edge of the signal.

10. The system of claim 9, wherein the eye diagram analyzer receives custom-designed specialized data patterns configured to replicate data traffic that emphasizes specific transitions or timing characteristics to analyze the 2D eye diagrams for the rising edge and the falling edge of the signal.

11. The system of claim 8, wherein increasing the symmetry of the eye opening results in improved data eye margins configured to enable data transfer at speeds of at least 9 gigabits per second (Gbps).

12. The system of claim 8, wherein the receiver includes a continuous-time linear equalizer (CTLE) adjuster configured to dynamically adjust CTLE coefficients to maintain a consistent vertical and horizontal eye margin.

13. The system of claim 12, wherein feedback circuitry and real-time monitoring circuitry is used for the dynamic adjustments of the CTLE coefficients and the duty cycle parameter.

14. A method comprising:
separately capturing a two-dimensional (2D) eye diagram for a rising edge and a 2D eye diagram for a falling edge of a receiver path signal using an eye diagram analyzer located in a receiver;
dynamically adjusting a duty cycle using a duty cycle adjuster located in a transmitter to increase symmetry between the rising edge and the falling edge of the receiver path signal; and
dynamically adjusting CTLE coefficients using a continuous-time linear equalizer (CTLE) adjuster.

15. The method of claim 14, wherein optimal CTLE coefficient and duty cycle settings are determined based on the captured 2D eye diagrams for the rising edge and the falling edge.

16. The method of claim 14, wherein increasing the symmetry results in a more symmetrical eye opening between the rising edge and the falling edge of the receiver path signal.

17. The method of claim 14, wherein increasing the symmetry results in improved data eye margins configured to enable data transfer at speeds of at least 9 gigabits per second (Gbps).

18. The method of claim 14, wherein the dynamic adjustments of the CTLE coefficients and the duty cycle maintain a consistent vertical and horizontal eye margin.

19. The method of claim 14, wherein feedback circuitry and real-time monitoring circuitry is used for the dynamic adjustments of the CTLE coefficients and the duty cycle.

20. The method of claim 14, wherein the eye diagram analyzer receives custom-designed specialized data patterns configured to replicate data traffic that emphasizes specific transitions or timing characteristics to analyze the 2D eye diagrams for the rising edge and the falling edge of the receiver path signal.
